(19) United States
(12) Patent Application Publication
(10) Pub. No.: US 2007/0218656 A1
(43) Pub. Date: Sep. 20, 2007

(54) SUBSTRATE PROCESSING APPARATUS AND SUBSTRATE PROCESSING METHOD

(76) Inventor: Masahiro MIYAGI, Kyoto (JP)

Correspondence Address: OSTROLENK FABER GERB & SOFFEN, 1180 AVENUE OF THE AMERICAS, NEW YORK, NY, 100368403, US

(21) Appl. No.: 11/686,470

(22) Filed: Mar. 15, 2007

(30) Foreign Application Priority Data
Mar. 15, 2006 (JP) 2006-71176

(51) Int. Cl. H01L 21/20

(52) U.S. Cl. 438/478

(57) ABSTRACT

A substrate processing apparatus comprises an applying part which is a two-fluid nozzle for applying droplets of a cleaning solution onto a substrate, a cleaning solution supply part for supplying the cleaning solution into the applying part, and a ring-shaped induction electrode located close to an outlet of the applying part. An electric potential difference is generated between the induction electrode and the conductive liquid contact part (i.e., the cleaning solution supply part and the cleaning solution tube in the applying part) to induce charge on the cleaning solution in the vicinity of the outlet. In the substrate processing apparatus, since the substrate is cleaned by the droplets of the cleaning solution on which charge having an opposite polarity to that of the electric potential of the substrate after cleaning is induced, it is possible to suppress charging of the substrate during and after cleaning.

### BACKGROUND OF THE INVENTION

1. Field of the Invention

The present invention relates to a technique for processing a substrate by applying a processing liquid onto the substrate.

2. Description of the Background Art

Conventionally, in manufacturing process of a semiconductor substrate (hereinafter, simply referred to as “substrate”), various processings are performed by supplying a processing liquid onto a substrate. For example, in a cleaning process of substrate, unwanted particles and the like adhering on the surface of the substrate are removed by applying a cleaning solution such as pure water onto the substrate.

Meanwhile, in such a cleaning process, it has been known that the whole surface of the substrate on which an insulating film is formed is charged by contacting with pure water. For example, in a case where an oxide film is formed on a surface of a substrate, the substrate is negatively charged and conversely, in a case where a resist film is formed on a surface of a substrate, the substrate is positively charged. When a surface charge of the substrate is large, there is a possibility of occurrence of re-adhesion of unwanted particles or damage on wiring caused by electric discharge during and after cleaning or the like. Therefore, various techniques for suppressing charging of a substrate in a substrate processing apparatus are suggested.

For example, Japanese Patent Application Laid-Open No. 2002-184660 (Document 1) discloses a technique for suppressing charging of a surface of a substrate in a cleaning apparatus where ionized nitrogen gas is purged into a processing space above the substrate, and the substrate is cleaned by applying a cleaning solution onto the substrate which is rotated. Japanese Patent Application Laid-Open No. 2005-183791 (Document 2) discloses a technique for suppressing charging of surfaces of substrates in an apparatus where the substrates are dipped into a cleaning solution stored in a process bath and a conductive CO2-dissolved water where carbon gas is dissolved into pure water is applied onto the substrates in exchanging of cleaning solution.

Japanese Patent Application Laid-Open No. 10-149893 (Document 3) discloses an apparatus for removing static electricity of charged substances, where pure water is ejected from a nozzle at high speed to generate fine droplets of the pure water which are charged by flow friction with the nozzle and the charged droplets are applied onto the charged substances. The apparatus can be applied to a charged semiconductor substrate after cleaning.

However, in the cleaning process performed in the ionized gas atmosphere as disclosed in Document 1, it is difficult to apply the ionized gas onto the surface of the substrate continuously and efficiently, and this causes a limitation of suppressing charging of the substrate. As disclosed in Document 2, when CO2-dissolved water is applied onto the substrates, if a copper wiring is formed on the substrates, the copper wiring could deteriorate because of contact with the acid CO2-dissolved water. Further, in such an apparatus for applying the CO2-dissolved water, since it is necessary to provide a unit for dissolving CO2 into pure water before application, the construction of the apparatus is complicated and upsized. In the apparatus shown in Document 3, it is not possible to suppress charging of the substrate during cleaning.

### SUMMARY OF THE INVENTION

The present invention is intended for a substrate processing apparatus for processing a substrate by applying a processing liquid onto the substrate. It is an object of the present invention to suppress charging of the substrate during processing.

The substrate processing apparatus comprises an applying part for applying a nonconductive processing liquid from an outlet onto a main surface of a substrate; a processing liquid supply part for supplying the processing liquid into the applying part; and an induction electrode which is electrically insulated from the applying part and located close to the outlet of the applying part or located at a position of the outlet, the induction electrode inducing charge on the processing liquid in the vicinity of the outlet by generating an electric potential difference between the induction electrode and a liquid contact part which is conductive and contacts the processing liquid in the applying part or the processing liquid supply part. According to the present invention, it is possible to suppress charging of the substrate during processing.

According to a preferred embodiment of the present invention, the applying part ejects droplets of the processing liquid onto the substrate. More preferably, the applying part generates the droplets of the processing liquid by mixing the processing liquid and carrier gas in the applying part or in the vicinity outside the outlet.

According to another preferred embodiment of the present invention, the induction electrode is a ring shape surrounding a central axis of the outlet. According to still another preferred embodiment of the present invention, the induction electrode is integrated with the applying part.

According to an aspect of the present invention, the liquid contact part is made of conductive resin or conductive carbon. According to another aspect of the present invention, the liquid contact part is at least provided in the processing liquid supply part, and the electric potential difference is generated between the processing liquid supply part and the induction electrode. It is also preferable that the liquid contact part is grounded.

According to still another aspect of the present invention, the substrate processing apparatus further comprises a surface electrometer for measuring an electric potential on the main surface of the substrate; and a control part for controlling an electric potential difference between the liquid contact part and the induction electrode on the basis of an output from the surface electrometer, concurrently with application of the processing liquid from the applying part.

The present invention is also intended for a substrate processing method for processing a substrate by applying a processing liquid onto the substrate.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a view showing a construction of a substrate processing apparatus in accordance with a first preferred embodiment;

FIG. 2 is a longitudinal sectional view showing the vicinity of an applying part;

FIG. 3 is a flowchart showing an operation flow for cleaning a substrate;

FIG. 4A is a view showing a distribution of electric potentials on the upper surface of the substrate;

FIG. 4B is a view showing a comparative example of a distribution of electric potentials on an upper surface of a substrate;

FIGS. 5 to 7 are sectional views each of which shows the vicinity of an applying part in a substrate processing apparatus in accordance with the second to fourth preferred embodiments;

FIG. 8 is a view showing a construction of a substrate processing apparatus in accordance with a fifth preferred embodiment; and

FIG. 9 is a flowchart showing a part of operation flow for cleaning a substrate.

### DESCRIPTION OF THE PREFERRED EMBODIMENTS

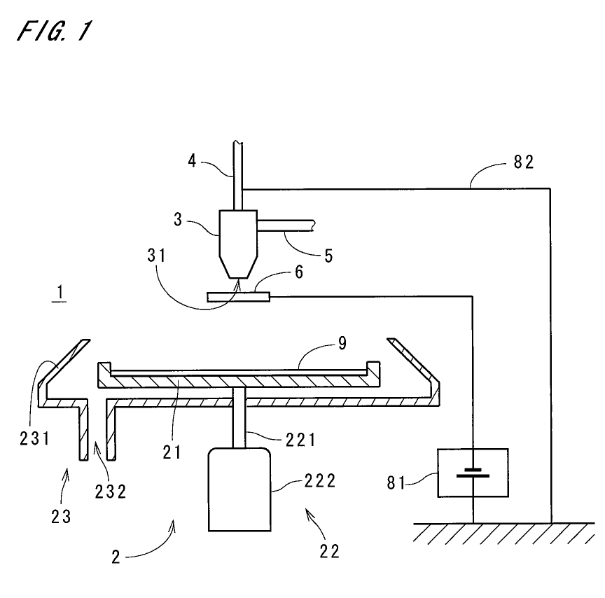

FIG. 1 is a view showing a construction of a substrate processing apparatus 1 in accordance with the first preferred embodiment of the present invention. The substrate processing apparatus 1 is an apparatus where a cleaning process is performed by applying a cleaning solution onto a semiconductor substrate 9 (hereinafter, simply referred to as “substrate 9”) on which an insulating film is formed and foreign substances such as unwanted particles adhering on the surface of the substrate 9 are removed. As the cleaning solution, a nonconductive liquid (pure water in the preferred embodiment) is used in the substrate processing apparatus 1. In the preferred embodiment, cleaning is performed on the substrate 9 where an oxide film is formed on the surface.

As shown in FIG. 1, the substrate processing apparatus 1 comprises a substrate holding part 2 holding the substrate 9 in contact with the bottom, an applying part 3 positioned above the substrate 9 for applying the cleaning solution onto an upper main surface of the substrate 9 (hereinafter, the upper main surface is referred to as “upper surface”), a cleaning solution supply part (i.e., processing liquid supply part) 4 which supplies the cleaning solution into the applying part 3 and has a circular section, a gas supply part 5 for supplying nitrogen (N2) gas into the applying part 3 independently from the cleaning solution supply part 4, and an induction electrode 6 located close to an outlet 31 of the applying part 3 between the applying part 3 and the substrate 9. In FIG. 1, a part of the substrate holding part 2 is shown cross-sectionally for convenience of illustration.

The substrate holding part 2 has a chuck 21 for holding the approximately disk-shaped substrate 9 in contact with the lower surface and the periphery of the substrate 9, a rotation mechanism 22 for rotating the substrate 9, and a process cup 23 covering the circumference of the chuck 21. The rotation mechanism 22 has a shaft 221 coupled to the bottom of the chuck 21 and a motor 222 for rotating the shaft 221. By driving the motor 222, the substrate 9 rotates together with the shaft 221 and the chuck 21. The process cup 23 has a side wall 231, located in the circumference of the chuck 21, for preventing the cleaning solution applied onto the substrate 9 from splashing around, and a drain outlet 232 which is provided in the bottom of the process cup 23 and discharges the cleaning solution applied onto the substrate 9.

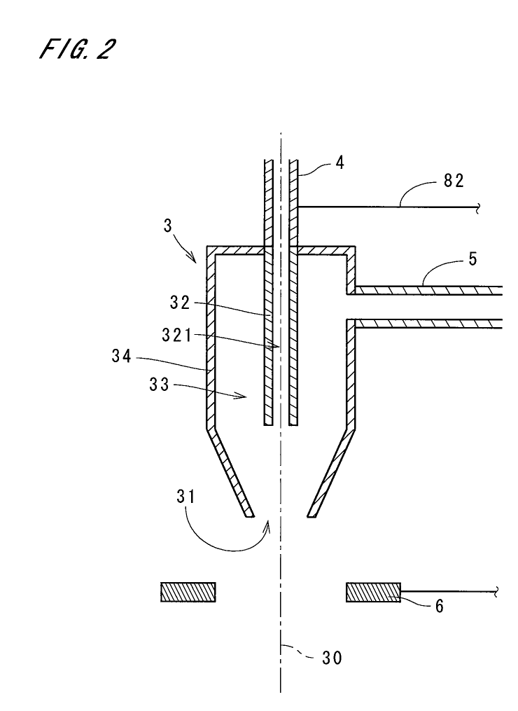

FIG. 2 is a longitudinal sectional view showing the vicinity of the applying part 3. As shown in FIG. 2, the applying part 3 is an internal mixing two-fluid nozzle, in which a cleaning solution tube 32 with a circular section is provided around the central axis 30 of the applying part 3 (the central axis of the outlet 31). The cleaning solution tube 32 is connected to the cleaning solution supply part 4 on the upper part of the applying part 3, and a space inside the cleaning solution tube 32 is a cleaning solution conduit 321 through which the cleaning solution supplied from the cleaning solution supply part 4 flows. A space between an external wall portion 34 of the applying part 3 and the cleaning solution tube 32 is a gas channel 33 through which carrier gas (for example, nitrogen gas or air) supplied from the gas supply part 5 flows, and the cleaning solution conduit 321 is surrounded by the gas channel 33.

In the applying part 3, a top end of the cleaning solution tube 32 is located at an upper position than the outlet 31 (i.e., the upper part in FIG. 2). The cleaning solution ejected from the cleaning solution tube 32 is mixed with the carrier gas in the applying part 3, fine droplets of the cleaning solution are generated and ejected onto the substrate 9 (see FIG. 1) from the outlet 31 together with the carrier gas. An inner diameter of the outlet 31 is about 2 to 3 mm.

The cleaning solution tube 32 of the applying part 3 (i.e., a portion forming the cleaning solution conduit 321 in the applying part 3) and the cleaning solution supply part 4 connected to the cleaning solution tube 32 are made of conductive carbon (preferably, such as amorphous carbon or glassy carbon), conductive resin (for example, conductive PEEK (poly-ether-ether-ketone), or conductive PTFE (poly-tetra-fluoro-ethylene)). In the preferred embodiment, the cleaning solution tube 32 and the cleaning solution supply part 4 are made of glassy conductive carbon. The glassy conductive carbon is hard carbon material with a uniform and dense structure, and it has excellent conductivity, chemical resistance, heat resistance, and the like.

In the substrate processing apparatus 1, the cleaning solution tube 32 and the cleaning solution supply part 4 are one cleaning solution supply tube for applying the cleaning solution onto the substrate 9, and the whole cleaning solution supply tube is a conductive liquid contact part which contacts the cleaning solution. In the substrate processing apparatus 1, a conductive line 82 is connected to the cleaning solution supply part 4 and as shown in FIG. 1, the cleaning solution supply part 4 and the cleaning solution tube 32 (see FIG. 2) are grounded through the conductive line 82.

As shown in FIG. 2, the induction electrode 6 is a ring shape surrounding the central axis 30 of the outlet 31, and an outer diameter of the induction electrode 6 is about 15 mm and an inner diameter is about 8 mm. The distance between the induction electrode 6 and the outlet 31 with respect to the direction of the central axis 30 is approximately 3 to 4 mm. The induction electrode 6 which is made of stainless steel and the applying part 3 are electrically insulated from each other.

In the substrate processing apparatus 1 shown in FIG. 1, the induction electrode 6 is electrically connected to a power supply 81 positioned outside the substrate processing apparatus 1 and an electric potential difference is generated between the induction electrode 6 and the conductive liquid contact part (i.e., the cleaning solution supply part 4 and the cleaning solution tube 32 (see FIG. 2)). Then, charge is induced on the cleaning solution in the vicinity of the outlet 31 of the applying part 3 and droplets of the cleaning solution having charge are ejected from the applying part 3.

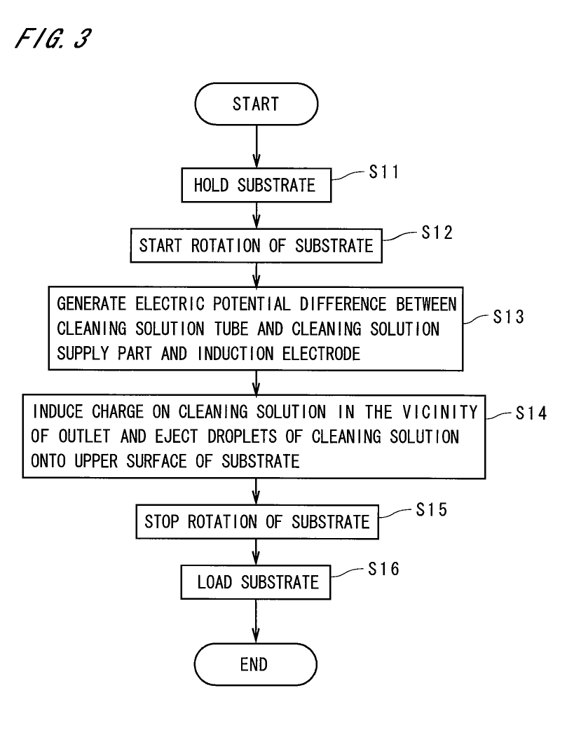

Next, discussion will be made on a cleaning process of the substrate 9 in the substrate processing apparatus 1. FIG. 3 is a flowchart showing an operation flow for cleaning the substrate 9. In the substrate processing apparatus 1, first, after the substrate 9 is held by the chuck 21 of the substrate holding part 2, the motor 222 of the rotation mechanism 22 is driven to start rotation of the substrate 9 (Steps S11, S12).

Subsequently, an electric potential difference is generated between the induction electrode 6 and the cleaning solution tube 32 and the cleaning solution supply part 4 of the applying part 3 and charge is induced on a portion in the vicinity of the outlet 31 in the applying part 3 (i.e., the portion is the top end of the cleaning solution tube 32) (Step S13). In the preferred embodiment, an electric potential of approximately −1000 V is applied to the induction electrode 6 and positive charge is induced in the vicinity of the outlet 31 in the applying part 3.

In the above state, the cleaning solution and nitrogen gas are supplied into the applying part 3, positive charge is induced on the cleaning solution in the vicinity of the outlet 31 and fine droplets of the cleaning solution are generated. The droplets of the cleaning solution on which the positive charge is induced are ejected (i.e., applied) onto the upper surface of the substrate 9 to perform cleaning of the substrate 9 (Step S14). In the substrate processing apparatus 1, since the applying part 3 reciprocally moves in a radial direction of the substrate 9 relatively to the substrate 9 which is rotated, the droplets of the cleaning solution are ejected over the whole upper surface of the substrate 9, to remove foreign substances such as unwanted particles adhering on the upper surface. In the substrate processing apparatus 1, while the droplets of the cleaning solution are ejected onto the substrate 9, induction of charge in the vicinity of the outlet 31 is parallelly and continuously performed by the induction electrode 6.

After ejection of the droplets onto the substrate 9 is performed for a predetermined time, application of the cleaning solution from the applying part 3 is stopped, electrical connection between the induction electrode 6 and the power supply 81 is turned off, and then induction of charge in the vicinity of the outlet 31 is stopped. Rotation of the substrate 9 is continued until the substrate 9 dries, and afterwards rotation of the substrate 9 is stopped (Step S15). The substrate 9 is loaded from the substrate processing apparatus 1 to complete the cleaning process of the substrate 9 (Step S16).

In the substrate processing apparatus 1, by colliding the fine droplets of the cleaning solution on the upper surface of the substrate 9 at high speed, unwanted fine particles such as organic matter adhering on the upper surface can be efficiently removed without damaging a fine pattern formed on the upper surface. Since nonconductive pure water is utilized as the cleaning solution, even if a copper wiring and the like are formed on the substrate 9, the wiring and the like are prevented to deteriorate due to contact with a conductive liquid (for example, an acid liquid such as CO2 solution). In the substrate processing apparatus 1, the two-fluid nozzle is used as the applying part 3 and therefore, it is possible to generate the droplets of the cleaning solution easily and minimize a mechanism for generation and ejection of the droplets.

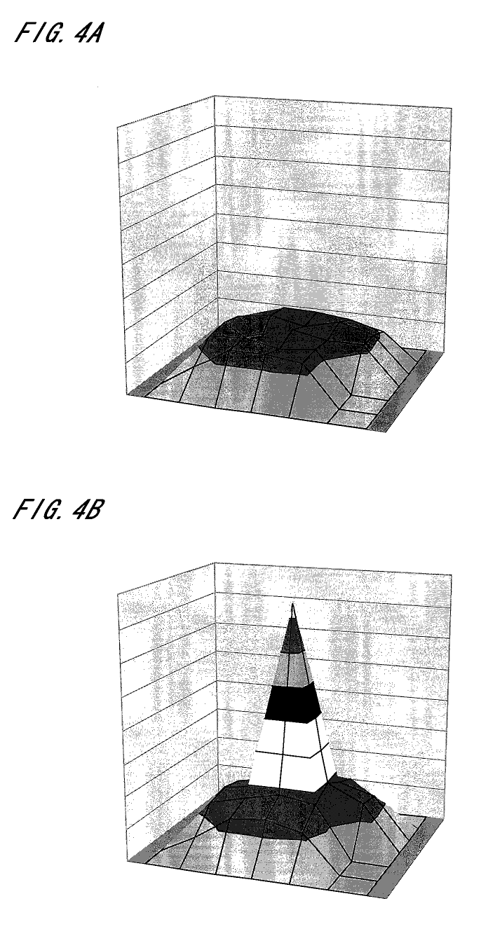

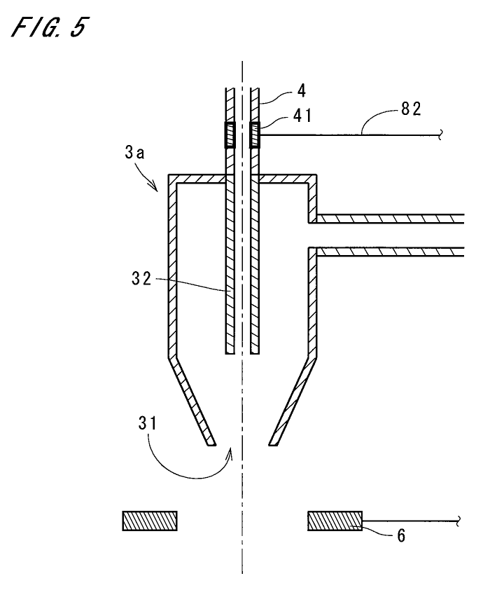

FIG. 4A is a view showing a distribution of electric potentials on the upper surface of the substrate 9 after cleaning in the substrate processing apparatus 1. FIG. 4B is a view showing a comparative example of a distribution of electric potentials on an upper surface of a substrate, in a case where a cleaning process is performed in a normal substrate processing apparatus in which induction of charge on the applying part is not performed. In FIG. 4B, an electric potential in the vicinity of the central portion of the substrate 9 where a surface charge (i.e., an absolute value of electric potential) is maximum is about −13 V and in FIG. 4A, an electric potential in an area of the substrate 9 where a surface charge is maximum is about −4 to −5 V. Since these substrates are hardly charged before cleaning, it is thought that the above electric potentials are generated during cleaning in the substrate processing apparatuses.

In the substrate processing apparatus 1 in accordance with the preferred embodiment, the substrate 9 is cleaned by the droplets of the cleaning solution on which positive charge (i.e., the charge having an opposite polarity to that of the electric potential of the substrate after cleaning in the comparative substrate processing apparatus) is induced and therefore, as shown in FIGS. 4A and 4B, it is possible to suppress charging of the substrate 9 during and after cleaning. The above induction of charge can be easily achieved by the induction electrode 6 located close to the outlet 31 of the applying part 3 while simplifying the construction of the substrate processing apparatus 1.

In the substrate processing apparatus 1, during cleaning of the substrate 9, induction of charge on the applying part 3 is continuously performed and it is possible to more suppress charging of the substrate 9. Further, since the induction electrode 6 is a ring shape surrounding the central axis 30 of the outlet 31, the charge can be almost uniformly induced on the vicinity of the outlet 31 without interfering with application of the cleaning solution from the outlet 31. As a result, it is possible to almost uniformly induce the charge on the plurality of droplets of the cleaning solution and suppress charging in the whole surface of the substrate 9 almost uniformly.

In the substrate processing apparatus 1, since the cleaning solution supply part 4 outside the applying part 3 is grounded though the conductive line 82, the charge can be more induced in the vicinity of the outlet 31 of the applying part 3 while simplifying the construction of the applying part 3, in comparison with the case where the conductive line 82 is connected inside the applying part 3. The conductive liquid contact part (i.e., the cleaning solution tube 32) and the induction electrode 6 are disposed closely and therefore, it is possible to efficiently perform induction of charge on the cleaning solution.

Further, since the cleaning solution tube 32 and the cleaning solution supply part 4 are made of conductive carbon or conductive resin, unlike the case where the cleaning solution tube 32 or the cleaning solution supply part 4 is made of metal, it is possible to prevent the cleaning solution from being contaminated because of getting mixed with metal powder or melting of the material of the liquid contact part, while keeping the conductivity of the liquid contact part. This prevents metal powder from adhering on the substrate 9 during cleaning or the like. Particularly, the cleaning solution tube 32 and the cleaning solution supply part 4 are made of glassy carbon and it is possible to more surely prevent the material of the liquid contact part from melting in the cleaning solution.

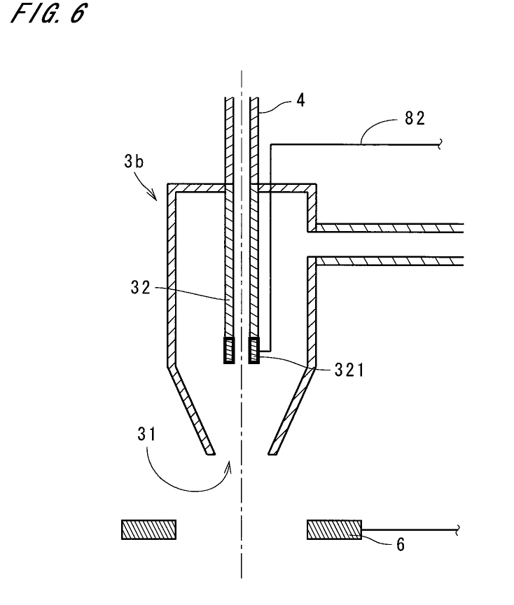

Next discussion will be made on a substrate processing apparatus in accordance with the second preferred embodiment of the present invention. FIG. 5 is a sectional view showing the vicinity of an applying part 3a in the substrate processing apparatus in accordance with the second preferred embodiment. In the substrate processing apparatus in accordance with the second preferred embodiment, the whole cleaning solution tube 32 of the applying part 3a is made of insulating materials (Teflon™ in the preferred embodiment). In the cleaning solution supply part 4, a portion excepting a cylindrical conductive liquid contact part 41 is made of insulating materials (PFA (per-fluoro-alkoxy) in the preferred embodiment), and the conductive liquid contact part 41 is made of glassy carbon and grounded through the conductive line 82. In FIG. 5, a section of the conductive liquid contact part 41 is surrounded by thick lines and shown by different hatching from the other portion of the cleaning solution supply part 4. Other constituent elements are the same as those of FIGS. 1 and 2 and represented by the same reference signs in the following discussion. An operation flow for cleaning the substrate 9 in the substrate processing apparatus in accordance with the second preferred embodiment is the same as that in the first preferred embodiment.

In the substrate processing apparatus in accordance with the second preferred embodiment, the induction electrode 6 is electrically connected to the power supply 81 (see FIG. 1), and an electric potential difference is generated between the induction electrode 6 and the conductive liquid contact part 41 of the cleaning solution supply part 4, and like in the first preferred embodiment, positive charge is induced on the cleaning solution in the vicinity of the outlet 31 of the applying part 3a. Then, cleaning of the substrate 9 is performed by the droplets of the cleaning solution on which the positive charge is induced and it is possible to suppress charging of the substrate 9 during and after cleaning. Since the conductive liquid contact part 41 grounded through the conductive line 82 is provided outside the applying part 3a, the construction of the applying part 3a can be simplified.

Next, discussion will be made on a substrate processing apparatus in accordance with the third preferred embodiment of the present invention. FIG. 6 is a sectional view showing the vicinity of an applying part 3b in the substrate processing apparatus in accordance with the third preferred embodiment. In the substrate processing apparatus in accordance with the third preferred embodiment, the whole cleaning solution supply part 4 is made of insulating materials (PFA in the preferred embodiment), and a portion excepting a top end 321 of the cleaning solution tube 32 in the applying part 3b is made of insulating materials (Teflon™ in the preferred embodiment). The top end 321 of the cleaning solution tube 32 is made of glassy carbon and grounded through the conductive line 82 as a conductive liquid contact part. Other constituent elements are the same as those of FIGS. 1 and 2 and represented by the same reference signs in the following discussion.

In the substrate processing apparatus in accordance with the third preferred embodiment, the induction electrode 6 is electrically connected to the power supply 81 (see FIG. 1), and an electric potential difference is generated between the induction electrode 6 and the top end 321 of the cleaning solution tube 32, and like in the first preferred embodiment, positive charge is induced on the cleaning solution in the vicinity of the outlet 31 of the applying part 3b. Then, cleaning of the substrate 9 is performed by the droplets of the cleaning solution on which the positive charge is induced and it is possible to suppress charging of the substrate 9 during and after cleaning. Since the induction electrode 6 and the top end 321 of the cleaning solution tube 32 which is the conductive liquid contact part are disposed closely, induction of charge on the cleaning solution can be efficiently performed.

Next, discussion will be made on a substrate processing apparatus in accordance with the fourth preferred embodiment of the present invention. FIG. 7 is a sectional view showing the vicinity of an applying part 3c in the substrate processing apparatus in accordance with the fourth preferred embodiment. As shown in FIG. 7, in the substrate processing apparatus in accordance with the fourth preferred embodiment, the ring-shaped induction electrode 6 is provided in the top end of the applying part 3c and integrated with the external wall portion 34 of the applying part 3c. A hole inside the induction electrode 6 forms the outlet 31 of the applying part 3c. In other words, the induction electrode 6 is located at the position of the outlet 31 in the applying part 3c. Also, it can be said that the induction electrode 6 is attached around the outlet 31 of the applying part 3c. Other constituent elements are the same as those of FIGS. 1 and 2 and represented by the same reference signs in the following discussion.

In the substrate processing apparatus in accordance with the fourth preferred embodiment, like in the first preferred embodiment, an electric potential difference is generated between the conductive liquid contact part (i.e., the cleaning solution tube 32 and the cleaning solution supply part 4) and the induction electrode 6 electrically insulated from the liquid contact part, positive charge is induced on the cleaning solution in the vicinity of the outlet 31 of the applying part 3c, and then cleaning of the substrate 9 is performed by the droplets of the above cleaning solution, whereby charging of the substrate 9 during and after cleaning can be suppressed. In the substrate processing apparatus in accordance with the fourth preferred embodiment, particularly, since the induction electrode 6 is integrated with the applying part 3c, it is possible to simplify the construction of the substrate processing apparatus.

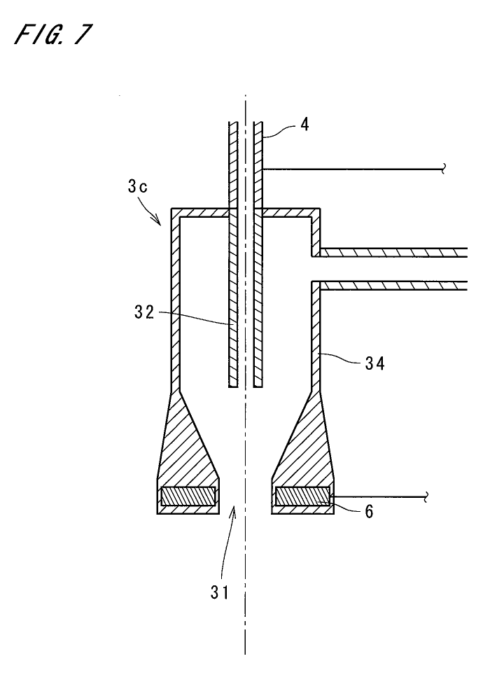

Next discussion will be made on a substrate processing apparatus 1a in accordance with the fifth preferred embodiment of the present invention. FIG. 8 is a view showing a construction of the substrate processing apparatus 1a. As shown in FIG. 8, the substrate processing apparatus 1a further comprises a surface electrometer 71 for measuring an electric potential on an approximately central portion of the upper surface of the substrate 9 and a control part 83 controlling an electric potential applied to the induction electrode 6, in addition to the constituent elements of the substrate processing apparatus 1 shown in FIG. 1. Other constituent elements are the same as those of FIGS. 1 and 2 and represented by the same reference signs in the following discussion.

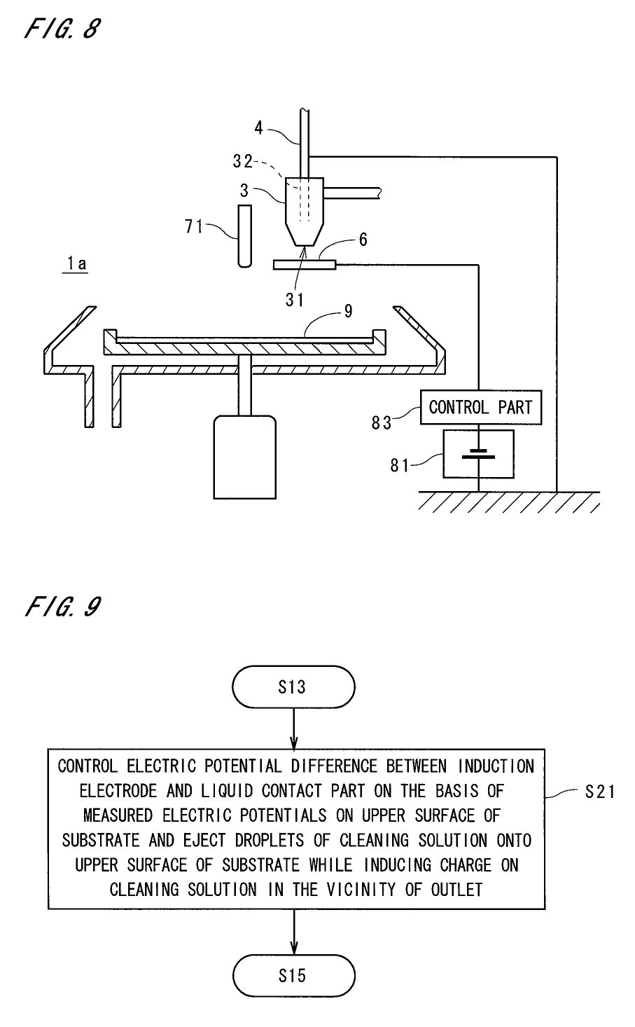

FIG. 9 is a flowchart showing a part of operation flow for cleaning the substrate 9 in the substrate processing apparatus 1a. In the substrate processing apparatus 1a, Step S21 in FIG. 9 is performed instead of Step S14 in FIG. 3, and the operations before and after Step S21 are the same as those of Steps S11 to S13 and Steps S15 and S16, respectively.

When cleaning of the substrate 9 is performed in the substrate processing apparatus 1a, like in the first preferred embodiment, after holding the substrate 9, rotation of the substrate 9 is started (FIG. 3: Steps S11, S12). Subsequently, an electric potential difference is generated between the induction electrode 6 and the conductive liquid contact part (i.e., the cleaning solution tube 32 and the cleaning solution supply part 4) (Step S13), positive charge is induced on the cleaning solution in the vicinity of the outlet 31 in the applying part 3 and fine droplets of the cleaning solution are ejected onto the upper surface of the substrate 9.

In the substrate processing apparatus 1a, concurrently with generation of the electrical potential difference and ejection (i.e., application) of the cleaning solution from the applying part 3, the electric potential on the upper surface of the substrate 9 are measured by the surface electrometer 71, an output from the power supply 81 is controlled by the control part 83 on the basis of an output from the surface electrometer 71 (i.e., the output from the surface electrometer 71 is an electric potential measured by the surface electrometer 71 and hereinafter referred to as “measured electric potential”). Then, the electric potential difference between the induction electrode 6 and the conductive liquid contact part is controlled, to control the charge induced on the droplets of the cleaning solution (Step S21).

Proportional control, PID control, or the like are used for control of the electric potential difference by the control part 83. The electric potential difference is made larger according to increase of the surface charge in the upper surface of the substrate 9 (i.e., increase of the absolute value of the measured electric potential), and it is possible to increase the charge induced on the cleaning solution and suppress charging of the substrate 9 more efficiently. Also, it is possible to prevent the substrate 9 from being charged to a reverse electric potential because of excessive induction of charge. When cleaning of the substrate 9 is finished, rotation of the substrate 9 is stopped after drying the substrate 9 and it is loaded from the substrate processing apparatus 1a (Steps S15, S16).

Though the preferred embodiments of the present invention have been discussed above, the present invention is not limited to the above-discussed preferred embodiments, but allows various variations.

For example, in the substrate processing apparatuses, the above cleaning process can be continuously performed on a plurality of substrates 9. In this case, the electrical connection between the induction electrode 6 and the power supply 81 may be kept in loading and unloading of the substrate 9. In the substrate processing apparatuses, since a voltage is only applied to the induction electrode 6 and current does not flow between the induction electrode 6 and the applying part 3, even if a user touches the induction electrode 6 or the applying part 3, it is possible to decrease the possibility of electric shock by providing a safety device for limiting current flowing out from the induction electrode 6.

In the substrate processing apparatuses in accordance with the above preferred embodiments, generation of the electric potential difference between the induction electrode 6 and the liquid contact part which is on the side of the applying part 3 may be performed by grounding the induction electrode 6 and connecting the liquid contact part to the power supply 81 or by connecting both electrodes of the power supply 81 to the induction electrode 6 and the liquid contact part, respectively. However, from the viewpoint of simplification of the construction of the substrate processing apparatus, it is preferable that the liquid contact part is grounded and the induction electrode 6 is connected to the power supply 81, like in the above preferred embodiments.

The whole applying part may be made of conductive material in the substrate processing apparatuses in accordance with the first to third and fifth preferred embodiments. The distance between the induction electrode 6 and the outlet 31 of the applying part with respect to the direction of the central axis 30 may be different from the distance described in the above preferred embodiments, as long as it is the distance where induction of charge in the vicinity of the outlet 31 can be performed with an actual power supply.

In the substrate processing apparatuses in accordance with the above preferred embodiments, a polarity of electric potential and a surface charge of the substrate which are created in cleaning are different depending on a kind of substrate (for example, a kind of insulating film or a kind of wiring metal which are formed on an upper surface of a semiconductor substrate and both kinds of insulating film and wiring metal), and therefore, the electric potential difference generated between the induction electrode 6 and the applying part in the substrate processing apparatus is changed according to kinds of substrate. For example, in a case where a resist film is formed on a substrate, the upper surface of the substrate is positively charged by cleaning and a positive voltage is applied to the induction electrode 6 to induce negative charge on the cleaning solution.

The applying part is not necessarily limited to the internal mixing two-fluid nozzle but may be an external mixing two-fluid nozzle, for example, which generates droplets of the cleaning solution by individually ejecting the cleaning solution and carrier gas outside the applying part and mixing them in the vicinity outside the outlet 31. In the substrate processing apparatus, there may be a case where droplets of a cleaning solution generated in another apparatus are supplied into the applying part and the droplets are ejected from the applying part together with carrier gas or only the cleaning solution is supplied into the applying part and ejected as the droplets.

Droplets of the cleaning solution are not necessarily applied from the applying part in the substrate processing apparatus. For example, a pillar of cleaning solution can be applied to perform cleaning of the substrate 9 or a cleaning solution in which ultrasonic wave is generated may be applied to perform cleaning of the substrate 9. As discussed above, since the substrate processing apparatus can suppress charging caused by cleaning of the substrate 9, it is more suitable for cleaning by the droplets where a surface charge of the substrate 9 becomes larger than cleaning by the pillar of cleaning solution.

In the substrate processing apparatus, a liquid other than pure water can be utilized as a nonconductive cleaning solution and for example, a ZEORORA™ of ZEON Corporation or a Novec™ HFE of 3M Company, which are fluorine-based cleaning solutions, can be used as a cleaning solution.

The substrate processing apparatuses in accordance with the above preferred embodiments may be utilized in various stages other than cleaning of substrate, and may be utilized, for example, in a rinsing process of a substrate cleaned with a chemical solution. In this case, a rinse agent such as pure water is used as a processing liquid supplied onto a substrate. Also, the substrate processing apparatus may be used for processing various substrates such as a printed circuit board or a glass substrate for a flat panel display, as well as a semiconductor substrate.

While the invention has been shown and described in detail, the foregoing description is in all aspects illustrative and not restrictive. It is therefore understood that numerous modifications and variations can be devised without departing from the scope of the invention.

This application claims priority benefit under 35 U.S.C. Section 119 of Japanese Patent Application No. 2006-71176 filed in the Japan Patent Office on Mar. 15, 2006, the entire disclosure of which is incorporated herein by reference.

What is claimed is:

1. A substrate processing apparatus for processing a substrate by applying a processing liquid onto said substrate, comprising:
an applying part for applying a nonconductive processing liquid from an outlet onto a main surface of a substrate;
a processing liquid supply part for supplying said processing liquid into said applying part; and
an induction electrode which is electrically insulated from said applying part and located close to said outlet of said applying part or located at a position of said outlet, said induction electrode inducing charge on said processing liquid in the vicinity of said outlet by generating an electric potential difference between said induction electrode and a liquid contact part which is conductive and contacts said processing liquid in said applying part or said processing liquid supply part.

2. The substrate processing apparatus according to claim 1, wherein
said applying part ejects droplets of said processing liquid onto said substrate.

3. The substrate processing apparatus according to claim 2, wherein
said applying part generates said droplets of said processing liquid by mixing said processing liquid and carrier gas in said applying part or in the vicinity outside said outlet.

4. The substrate processing apparatus according to claim 1, wherein
said induction electrode is a ring shape surrounding a central axis of said outlet.

5. The substrate processing apparatus according to claim 1, wherein
said induction electrode is integrated with said applying part.

6. The substrate processing apparatus according to claim 1, wherein
said liquid contact part is made of conductive resin or conductive carbon.

7. The substrate processing apparatus according to claim 1, wherein
said liquid contact part is at least provided in said processing liquid supply part, and said electric potential difference is generated between said processing liquid supply part and said induction electrode.

8. The substrate processing apparatus according to claim 1, wherein
said liquid contact part is grounded.

9. The substrate processing apparatus according to claim 1, further comprising:
a surface electrometer for measuring an electric potential on said main surface of said substrate; and
a control part for controlling an electric potential difference between said liquid contact part and said induction electrode on the basis of an output from said surface electrometer, concurrently with application of said processing liquid from said applying part.

10. A substrate processing method for processing a substrate by applying a processing liquid onto said substrate, comprising the steps of:
a) applying a nonconductive processing liquid onto a main surface of a substrate from an applying part connected to a processing liquid supply part; and
b) inducing charge on said processing liquid in the vicinity of an outlet of said applying part concurrently with said step a), by generating an electric potential difference between an induction electrode which is electrically insulated from said applying part and located close to said outlet or located at a position of said outlet and a liquid contact part which is conductive and contacts said processing liquid in said applying part or said processing liquid supply part.

11. The substrate processing method according to claim 10, wherein
droplets of said processing liquid are ejected onto said substrate in said step a).

12. The substrate processing method according to claim 10, further comprising the steps of:
c) measuring an electric potential on said main surface of said substrate; and
d) controlling an electric potential difference between said liquid contact part and said induction electrode on the basis of said electric potential measured in said step c), wherein
said steps c) and d) are performed concurrently with said steps a) and b).

13. The substrate processing method according to claim 10, wherein
said step b) is continuously performed during said step a).

14. The substrate processing apparatus according to claim 3, wherein
said induction electrode is a ring shape surrounding a central axis of said outlet.

15. The substrate processing apparatus according to claim 3, wherein
said induction electrode is integrated with said applying part.

16. The substrate processing apparatus according to claim 3, wherein
said liquid contact part is made of conductive resin or conductive carbon.

17. The substrate processing apparatus according to claim 3, wherein
said liquid contact part is at least provided in said processing liquid supply part, and said electric potential difference is generated between said processing liquid supply part and said induction electrode.

18. The substrate processing apparatus according to claim 3, wherein
said liquid contact part is grounded.

19. The substrate processing apparatus according to claim 3, further comprising:
a surface electrometer for measuring an electric potential on said main surface of said substrate; and
a control part for controlling an electric potential difference between said liquid contact part and said induction electrode on the basis of an output from said surface electrometer, concurrently with application of said processing liquid from said applying part.

20. The substrate processing method according to claim 11, further comprising the steps of:
c) measuring an electric potential on said main surface of said substrate; and
d) controlling an electric potential difference between said liquid contact part and said induction electrode on the basis of said electric potential measured in said step c), wherein
said steps c) and d) are performed concurrently with said steps a) and b).

21. The substrate processing method according to claim 11, wherein
said step b) is continuously performed during said step a).
